(19) United States
(12) Patent Application Publication
(10) Pub. No.: US 2011/0233560 A1
(43) Pub. Date: Sep. 29, 2011

(54) Electrode for silicon carbide, silicon carbide semiconductor element, silicon carbide semiconductor device and method for forming electrode for silicon carbide

(75) Inventors: Junichi Koike, Miyagi (JP); Akihiro Shibatomi, Miyagi (JP); Kunhwa Jung, Miyagi (JP); Yuji Sutou, Miyagi (JP)

(73) Assignee: Advanced Interconnect Materials, LLC, Sendai-shi (JP)

(21) Appl. No.: 13/065,222

(22) Filed: Mar. 16, 2011

(30) Foreign Application Priority Data
Mar. 16, 2010 (JP) 2010-59827

(51) Int. Cl. H01L 29/12; H01L 23/48; H01L 21/283; B82Y 99/00; B82Y 40/00

(52) U.S. Cl. 257/77; 257/744; 438/602; 977/755; 257/E23.01; 257/E29.068; 257/E21.159

(57) ABSTRACT

An electrode for silicon carbide includes a silicide region which is provided in contact with a surface of a silicon carbide (SiC) layer and a carbide region which is provided on the silicide region. The silicide region contains a silicide of a first metal in more amount than a carbide of a second metal whose free energy of carbide formation is less than that of silicon (Si). The carbide region contains the carbide of the second metal in more amount than the silicide of the first metal.

This application claims priority under 35 U.S.C. §119 from Japanese patent application serial No. 2010-59827, filed Mar. 16, 2010, entitled “Electrode for silicon carbide, silicon carbide semiconductor element, silicon carbide semiconductor device and method for forming electrode for silicon carbide,” which are incorporated herein by reference in its entirety.

### TECHNICAL FIELD

The present invention relates to an electrode for silicon carbide provided on a silicon carbide single crystal substrate such as 3C type of cubic crystal, and 2H type, 4H type and 6H type of hexagonal crystal, or on a crystal layer of these crystal types (hereinafter, collectively referred to as a “silicon carbide layer”), a silicon carbide semiconductor element provided with the electrode for silicon carbide as an ohmic electrode, a silicon carbide semiconductor device and a method for forming an electrode for silicon carbide.

### BACKGROUND OF THE INVENTION

Silicon carbide (SiC) of 4H or 6H type of hexagonal crystals are known as so-called wide bandgap semiconductors that exceed 3 electron volts (unit of energy: eV) at room temperature. Because of this, n type or p type silicon carbide semiconductors are used for manufacturing high voltage resistant diodes for switching high capacity power sources. For example, they are used in the manufacture of a high voltage resistant Schottky barrier having a voltage resistance of 600 volts (unit of voltage: V).

To manufacture a silicon carbide semiconductor element for configuring a silicon carbide semiconductor device, an electrode for silicon carbide semiconductor is inevitably required. Especially, for configuring a silicon carbide power (power) semiconductor element such as inverters, an ohmic electrode having low contact resistance to the silicon carbide is required. This is because with an electrode with high contact resistance, the heat loss also becomes large, thereby disrupting the manifestation of the characteristics of the silicon carbide semiconductor element.

Reflecting on the technologies relating to the electrode for a silicon carbide semiconductor, conventionally, a technology for forming an ohmic electrode from only nickel (Ni) is known (for example, see non-patent reference 1). There is an example of configuring from nickel and titanium (element symbol: Ti) laminated body (for example, see non-patent reference 2). Further, there is an example of study of the reaction with silicon carbide by sandwiching a film of vanadium (element symbol: V) or niobium (element symbol: Nb) between silicon carbide and these metal films (for example, see non-patent references 3 and 4).

### PRIOR ART DOCUMENTS

### Non-Patent Document

[Non-patent reference 1] F. La Via, F. Roccaforte, A. Makhtari, V. Raineri, P. Musumeci, and L. Calagno, Microelectronic Engineering, vol. 60 (2002) p. 269

[Non-patent reference 2] J. H. Park and P. H. Holloway, Journal of Vacuum Science and Technology, B23 (2005) 2530.

[Non-patent reference 3] J. Feng, M. Naka and J. C. Schuster, Transaction of Japan Welding Institute, 23 (1994) 191.

[Non-patent reference 4] T. Fukai, M. Naka and J. C. Schuster, Journal of Materials Synthesis and Processing, 6 (1998) 387.

By the way, if we try to configure an electrode of semiconductor silicon carbide using a film of only nickel, particles (carbon clusters) composed of carbon (element symbol: C) or cavities (voids) deposit in the region near the contact interface between the silicon carbide substrate or the silicon carbide layer and the nickel film according to the chemical equation (1).

SiC+2Ni→Ni₂Si+C (1)

These carbon clusters and voids weaken the adhesion in the junction between the silicon carbide and the silicide electrode containing nickel. In addition, the electrode surface becomes rough, due to which it will not be possible to provide, for example, a gold (element symbol: Au) layer for connecting (bonding) with strong adhesion on the surface of the electrode. Accordingly, there is a drawback of difficulty of bonding using a gold wire.

The chemical reactions that occur when providing an electrode on silicon carbide from a nickel and titanium laminated body can be represented by the chemical equation (2).

SiC+2Ni+Ti→Ni₂Si+TiC (2)

When providing an electrode by adding titanium to nickel, since carbon and titanium react easily to form titanium carbide (TiC), it becomes possible to prevent the formation of carbon clusters which weaken the adhesion between the silicon carbide and the electrode. To be more explicit, it is reported that the deposition of carbon can be suppressed if the thickness of the titanium film provided on the surface of the silicon carbide is 20 nanometer (nm) and the thickness of the nickel film provided on the titanium film is 30 nm (see non-patent reference 2). However, the electrical resistance of titanium carbide (TiC) being high, currently the obtained contact resistance is (3.3±2.5)×10⁻⁴ Ω·cm², which is about 1 order of magnitude larger compared to the case of using only nickel.

An additional drawback of forming an electrode for silicon carbide from a laminated body of nickel and titanium or vanadium manifests when providing an electrode on the silicon carbide to which nitrogen (symbol: N) has been added to the silicon carbide for conferring n-type conductivity. If nickel and titanium or vanadium are employed, titanium or vanadium will extract the nitrogen that has been added in the n-type silicon carbide, thereby forming titanium nitride (TiN) or vanadium nitride (VN). Due to this, there will be a problem of increased electrical resistance in the region from which nitrogen was removed.

The present invention has been made to solve the above problems in the prior art. The present invention intends to provide an electrode for silicon carbide, a silicon carbide semiconductor element, and a silicon carbide semiconductor device provided with the electrode for silicon carbide, and a method for providing an electrode for silicon carbide which can improve the adhesion to the silicon carbide layer by suppressing the formation carbon clusters, etc. that reduce the adhesion to the silicon carbide layer, and which can also reduce the current flow resistance of the electrode by suppressing the extraction of nitrogen contained in the silicon carbide layer.

### SUMMARY OF THE INVENTION

To accomplish the above objectives,

(1) The first invention of the present invention is an electrode for silicon carbide including:

a silicide region which is provided in contact with a surface of a silicon carbide (SiC) layer, the silicide region containing a silicide of a first metal in more amount than a carbide of a second metal whose free energy of carbide formation is less than that of silicon (Si); and

a carbide region which is provided on the silicide region, the carbide region containing the carbide of the second metal in more amount than the silicide of the first metal.

(2) The second invention of the present invention is the electrode for silicon carbide according to the item (1), wherein

the silicon carbide layer contains nitrogen, and

an atomic concentration of nitrogen in the carbide region is not more than an atomic concentration of nitrogen in the silicon carbide layer in a section where an atomic concentration of carbon (C) in the carbide region is maximum.

(3) The third invention of the present invention is the electrode for silicon carbide according to the item (1), wherein

the silicon carbide layer contains nitrogen, and

an atomic concentration of nitrogen in the carbide region is not more than an atomic concentration of nitrogen in the silicon carbide layer.

(4) The fourth invention of the present invention is the electrode for silicon carbide according to the item (1), wherein a thickness of the carbide region is not more than a thickness of the silicide region.

(5) The fifth invention of the present invention is the electrode for silicon carbide according to the item (1), wherein a thickness of the carbide region is not less than 10 nanometer (nm), and is not more than one-half of the thickness of the silicide region.

(6) The sixth invention of the present invention is the electrode for silicon carbide according to the item (1), wherein the second metal element is a metal element having a free energy of nitride formation higher than that of silicon.

(7) The seventh invention of the present invention is the electrode for silicon carbide according to the item (6), wherein the second metal element is a metal element having a free energy of nitride formation higher than a free energy of carbide formation.

(8) The eighth invention of the present invention is the electrode for silicon carbide according to the item (7), wherein the second metal element is niobium (Nb).

(9) The ninth invention of the present invention is a silicon carbide semiconductor element including the electrode for silicon carbide according to the item (1) as an ohmic electrode.

(10) The tenth invention of the present invention is a silicon carbide semiconductor device including the silicon carbide semiconductor element according to the item (9).

(11) The eleventh invention of the present invention is a method for forming an electrode for silicon carbide including:

depositing a second metal film on a surface of a silicon carbide layer, the second metal film including a second metal which has a free energy of carbide formation smaller than that of silicon;

depositing a first metal film on the second metal film, the first metal film including a first metal that can easily bond with silicon to form a silicide, and

heating a laminated body of the second metal film and the first metal film provided on the silicon carbide layer, thereby bonding the first metal with the silicon in the silicon carbide layer, bonding the second metal with the carbon of the silicon carbide layer, forming a silicide region containing larger amount of the silicide of the first metal than the carbide of the second metal on the silicon carbide layer, and forming a carbide region containing larger amount of the carbide of the second metal than the silicide of the first metal on the silicide region.

(12) The twelfth invention of the present invention is the method for forming the electrode for silicon carbide according to the item (11), wherein the silicon carbide layer contains nitrogen, and the laminated body of the second metal film and the first metal film is heated in an inert gas or in vacuum at a temperature of not less than 800° C. and not more than 1200° C. for a period of not less than 1 minute and not more than 30 minutes.

(13) The thirteenth invention of the present invention the method for forming the electrode for silicon carbide according to the item (11), wherein the silicon carbide layer contains nitrogen, and the laminated body of the second metal film and the first metal film is heated in an inert gas or in vacuum at a temperature of not less than 850° C. and not more than 1150° C. for a period of not less than 1 minute and not more than 15 minutes.

(14) The fourteenth invention of the present invention is the method for forming the electrode for silicon carbide according to the item (11), wherein a film thickness of the second metal film is not more than a film thickness of the first metal film.

(15) The fifteenth invention of the present invention is the method for providing the electrode for silicon carbide according to the item (14), wherein the film thickness of the second metal film is not less than 10 nm and not more than 150 nm, and the film thickness of the first metal film is not less than double of the film thickness of the second metal film and is not less than 20 nm and not more than 300 nm.

(16) The sixteenth invention of the present invention is a method for forming an electrode for silicon carbide comprising:

depositing a second metal film on a surface of a silicon carbide layer, the second metal film including a second metal which has a free energy of carbide formation smaller than that of silicon;

depositing a first metal film on the second metal film, the first metal film including a first metal that can easily bond with silicon to form a silicide, and

heating a laminated body of the second metal film and the first metal film provided on the silicon carbide layer in an inert gas or in vacuum at a temperature of not less than 800° C. and not more than 1200° C. for a period of not less than 1 minute and not more than 30 minutes.

According to the first invention of the present invention, an electrode for silicon carbide includes a silicide region which is provided in contact with a surface of a silicon carbide (SiC) layer, the silicide region containing a silicide of a first metal in more amount than a carbide of a second metal whose free energy of carbide formation is less than that of silicon (Si); and a carbide region which is provided on the silicide region, the carbide region containing the carbide of the second metal in more amount than the silicide of the first metal. Because the carbide region is constituted from the second metal whose free energy of carbide formation is less than that of silicon, by a function of the second metal capturing the carbon liberated from the silicon carbide layer, the formation of carbon clusters and voids at the surface of the silicon carbide layer can be suppressed. Therefore, the adhesion between the electrode and silicon carbide layer can be improved and strengthened. Here, the free energy of carbide formation is a negative value, and a lower free energy of carbide formation means the absolute value is larger, and is more stable as carbide.

Further, because the silicide region is provided so as to be in contact with the silicon carbide layer surface, it becomes possible to provide a electrode of low contact resistance with regard to the silicon carbide layer.

According to the second invention of the present invention, the atomic concentration of nitrogen in the carbide region is not more than the atomic concentration of nitrogen in the silicon carbide layer in the section where the atomic concentration of carbon (C) in the carbide region is maximum, Therefore, since extraction of nitrogen from the silicon carbide layer is suppressed, and in addition, the formation of a nitride of the second metal, which has high electrical resistance, in the carbide region can be suppressed, it becomes possible to provide a low current flow resistance electrode for silicon carbide.

According to the third invention of the present invention, the atomic concentration of nitrogen in the carbide region is not more than the atomic concentration of nitrogen in the silicon carbide layer Therefore, since drawing out of nitrogen from the silicon carbide layer is suppressed, and in addition, the formation of a nitride of the second metal, which has high electrical resistance, in the carbide region can be suppressed, it becomes possible to provide a low current flow resistance electrode for silicon carbide.

According to the fourth invention of the present invention, with a carbide generally having a higher electrical resistance than a silicide, since the thickness of the carbide region is not more than the thickness of the silicide region, it becomes possible to provide a low current flow resistance electrode for silicon carbide.

According to the fifth invention of the present invention, particularly, the thickness of the carbide region is not less than 10 nanometer (nm), and is not more than one-half of the thickness of the silicide region. In other words, the carbide formation region is of such a thickness that it will form that much amount of carbide sufficient for reliably capturing the carbon liberated from silicon carbide, and at the same time, is of such a thickness that can suppress an unwanted rise in the electrical resistance due to the presence of the carbide region, which generally has a higher electrical resistance than silicide. Therefore, it becomes possible to provide a low current flow resistance electrode for silicon carbide.

According to the sixth invention of the present invention, the second metal element is a metal element having a free energy of nitride formation higher than that of silicon Accordingly, since the formation of a high electrical resistance carbon nitride in the carbide region can be suppressed, it becomes possible to provide an electrode with superior ohmic properties having a low current flow resistance. Here, the free energy of nitride formation is a negative value similar to the free energy of carbide formation. A smaller free energy of nitride formation means the absolute value is large, and is more stable as nitride.

According to the seventh invention of the present invention, the second metal element constitutes a carbide region as the metal element whose free energy of nitride formation is higher than that of silicon, and also higher than the free energy of carbide formation. Accordingly, the effect of providing an electrode of superior ohmic properties with a low current flow resistance can be further enhanced.

According to the eighth invention of the present invention, niobium has been chosen as the second metal element that constitutes the carbide region as the metal element whose free energy of nitride formation is higher than that of silicon, and also higher than the free energy of carbide formation. Accordingly, the effect of providing a electrode with superior ohmic properties having a low current flow resistance can be further enhanced.

According to the ninth invention of the present invention, the silicon carbide semiconductor element includes the electrode for silicon carbide as an ohmic electrode. The electrode for silicon carbide has a low electrical resistance since the silicide region is disposed so as to be in contact with the surface of silicon carbide, and in addition, has a superior adhesion to the silicon carbide since it is configured by laminating the carbide region on the silicide region. Therefore, a high voltage-resistant Schottky barrier diode with low heat loss and high efficiency can be provided.

According to the tenth invention of the present invention, the silicon carbide semiconductor element such as the high voltage-resistant Schottky barrier diode with low heat loss and high efficiency is provided, and the silicon carbide semiconductor device is configured employing such a silicon carbide semiconductor element. Therefore, it can contribute, for example, to providing devices such as high efficiency inverters.

According to the eleventh invention of the present invention, first, the second metal film is deposited on the surface of the silicon carbide layer, the second metal film including the second metal which has a small free energy of carbide formation and can easily form a carbide, and then, the first metal film that can easily form a silicide is deposited, thereby forming a laminated body (the laminated body formed from an initial layer order). Next, the laminated body is heated, thereby inverting the initial layer order so as to provide the electrode for silicon carbide from the laminated body in which are disposed the silicide region principally containing the silicide of the first metal on the surface of the silicon carbide, and the carbide region principally containing the carbide of the second metal on that silicide region. Therefore, it becomes possible to dispose the carbide region of the second metal, which is formed by capturing the carbon which comes after getting liberated from the silicon carbide, away from the surface of the silicon carbide. As a result, the effect of suppressing the formation of carbon cluster and voids at the surface of silicon carbide can be obtained.

Moreover, according to the eleventh invention of the present invention, since the low electrical resistance silicide layer of the first metal is disposed so as to be in contact with the surface of silicon carbide by inverting the initial layer order, it can contribute to providing an electrode of small electrical contract resistance for the silicon carbide.

According to the twelfth invention of the present invention, the heating for inverting the initial layer order was carried out in an inert gas or under vacuum at a temperature of not less than 800° C. and not more than 1200° C. for a period of not less than 1 minute and not more than 30 minutes. With this, in the carbide region of the second metal, which is located on the silicide region of the first metal, the atomic concentration of nitrogen in the section where the atomic concentration of carbon is maximum can be effectively kept low. In particular, it contributes to reducing the atomic concentration of nitrogen in that section to be not more than the atomic concentration of nitrogen in the silicon carbide. Accordingly, since the formation of a nitride or a carbon nitride that can enhance the electrical resistance in the carbide region can be suppressed, it contributes in providing an electrode with a low current flow resistance for silicon carbide.

According to the thirteenth invention of the present invention, the heating for inverting the initial layer order was carried out in an inert gas or under vacuum at a temperature of not less than 850° C. and not more than 1150° C. for a period of not less than 1 minute and not more than 15 minutes. Due to this, a maximum atomic concentration of nitrogen in the entire inside of the carbide region on the silicide region can be maintained to be not more than the atomic concentration of nitrogen in the silicon carbide layer. Therefore, since the formation of nitride or carbon nitride in the carbide region can be suppressed, in particular, it becomes possible to provide an electrode with a low current flow resistance for silicon carbide.

According to the fourteenth invention of the present invention, in the initial layer order, the film thickness of the second metal film provided on the surface of the silicon carbide was made not more than the film thickness of the first metal film that is formed over the second metal film. With this, the carbide region whose thickness is not more than the thickness of the silicide region can advantageously be formed, which results in reducing the thickness of a carbide region of high electrical resistance. Therefore, it becomes convenient to provide an electrode with a low current flow resistance for silicon carbide.

According to the fifteenth invention of the present invention, the film thickness of the second metal film is not less than 10 nm and not more than 150 nm, and the film thickness of the first metal film is not less than double of the film thickness of the second metal film and is not less than 20 nm and not more than 300 nm. With this, both the carbide region with a thickness of not less than 10 nm and the silicide region with a thickness of not less than twice the thickness of the carbide region and not more than 300 nm can be effectively formed. Accordingly, it becomes possible to provide the silicide region with a thickness adequate enough to obtain a low contact resistance with the silicon carbide, and more over, to provide the carbide region with a thickness adequate enough to satisfactorily capture the carbon that is released from the silicon carbide. Therefore, it becomes possible to form an electrode with a low current flow resistance for silicon carbide.

According to the sixteenth invention of the present invention, first, the second metal film is deposited on the surface of the silicon carbide layer, the second metal film including the second metal which has a small free energy of carbide formation and can easily form a carbide, and then, the first metal film that can easily form a silicide is deposited, thereby forming a laminated body (the laminated body formed from an initial layer order). Next, the laminated body is heated under the specific condition. With this, the initial layer order is inverted so as to provide the electrode for silicon carbide from the laminated body in which are disposed the silicide region principally containing the silicide of the first metal on the surface of the silicon carbide, and the carbide region principally containing the carbide of the second metal on that silicide region. Therefore, it becomes possible to dispose the carbide region of the second metal, which is formed by capturing the carbon which comes after getting liberated from the silicon carbide, away from the surface of the silicon carbide. As a result, the effect of suppressing the formation of carbon cluster and voids at the surface of silicon carbide can be obtained.

### BRIEF DESCRIPTION OF DRAWINGS

FIG. 1 shows a schematic of the configuration of the electrode for silicon carbide provided in the present invention.

FIG. 2 depicts the steps for forming the electrode for silicon carbide in the example. (a) shows the first half, and (b) shows the second half.

FIG. 3 shows the transmission electron microscopy image of the sectional structure of the electrode for silicon carbide formed in the example for the case of niobium film as the second metal film.

FIG. 4 shows the transmission electron microscopy image of the sectional structure of the electrode for silicon carbide formed in the comparative example for the case of vanadium film as the second metal film.

FIG. 5 shows the transmission electron microscopy image of the sectional structure of the electrode for silicon carbide formed in the comparative example for the case of titanium film as the second metal film.

FIG. 6 shows the results of measurement of composition distribution of the laminated body of the electrode for silicon carbide formed in the example for the case of niobium film as the second metal film.

FIG. 7 shows the results of measurement of composition distribution of the laminated body of the electrode for silicon carbide formed in the comparative example for the case of vanadium film as the second metal film.

FIG. 8 shows the results of measurement of composition distribution of the laminated body of the electrode for silicon carbide formed in the comparative example for the case of titanium film as the second metal film.

FIG. 9 shows the results of measurement of interface contact resistivity between the obtained electrode for silicon carbide and the silicon carbide.

### DETAILED DESCRIPTION OF THE INVENTION

The embodiment of the present invention is described below.

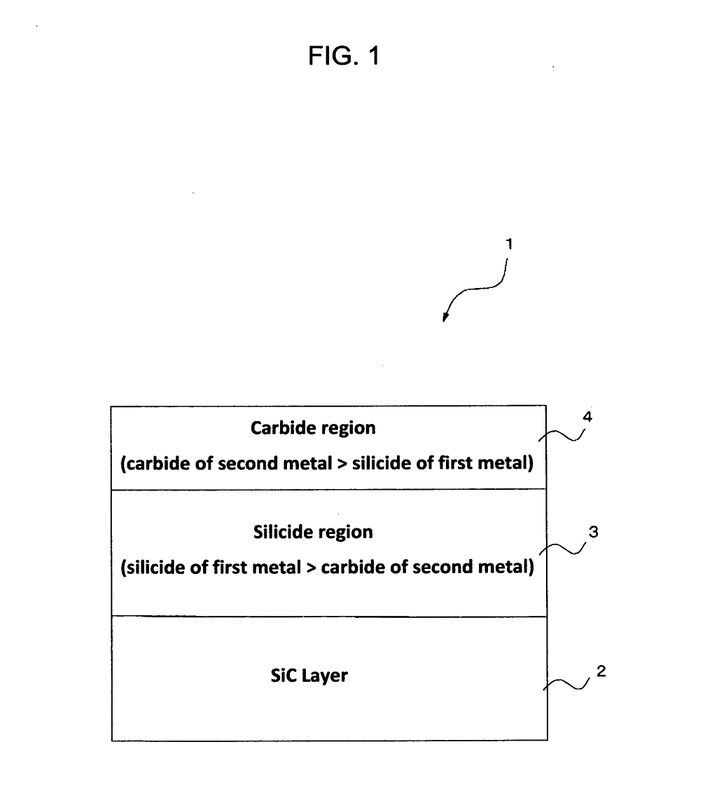

FIG. 1 shows a schematic of a configuration of an electrode for silicon carbide provided in the present invention. In FIG. 1, an electrode for silicon carbide 1 of the present invention includes a silicide region 3 which is provided in contact with a surface of a silicon carbide layer (SiC layer) 2, the silicide region 3 containing a silicide of a first metal in more amount than a carbide of a second metal whose free energy of carbide formation is less than that of silicon (Si), and a carbide region 4 which is provided on the silicide region 3, the carbide region 4 containing the carbide of the second metal in more amount than the silicide of the first metal.

The silicon carbide layer 2 is a single crystal substrate of such as 3C type of cubic crystal, or 2H type, 4H type or 6H type of hexagonal crystal, or a crystal layer of these crystal types. These single crystal substrate or the crystal layer of these crystal types are collectively called here as “silicon carbide layer.” In particular, 4H type or 6H type hexagonal crystalline silicon carbide containing larger amount of nitrogen (element symbol: N) than acceptor type impurities (p-type impurity) such as aluminum (element symbol: Al) can be advantageously employed to provide the electrode of the present invention. The electrode for silicon carbide of the present invention can be provided both on a silicon surface and a carbon surface.

In the present invention, the electrode for silicon carbide, can be formed from the laminated body made by stacking various types of metal films as described above. For example, it may be configured by a laminated body, obtained by stacking films of two different types of metals (metal films), formed on the silicon carbide surface of a 6H type single crystal silicon carbide substrate or a 6H type silicon carbide layer. In the present invention, one of the different types of metal is a metal element that can easily form a silicide with the silicon (element symbol: Si) of the silicon carbide. For example, this metal element can be cobalt (element symbol: Co), nickel (element symbol: Ni), ruthenium (element symbol: Ru), palladium (element symbol: Pd), platinum (element symbol: Pt), iridium (element symbol: Ir), osmium (element symbol: Os), etc. These metals are referred to as a first metal in the present invention.

The other one of the different types of metal is a metal element whose free energy of carbide formation is less than that of silicon. That is, a metal element that can easily form carbide. For example, this metal element can be titanium (element symbol: Ti), vanadium (element symbol: V), tantalum (element symbol: Ta), niobium (element symbol: Nb), zirconium (element symbol: Zr), etc. In the present invention, these metal elements that can easily form carbide are referred to as a second metal in comparison with the first metal. Example of the carbide is, for example, niobium carbide (compositional formula NbₓC_{y}; for example, x=2 and y=1).

In the present invention, the electrode for silicon carbide is composed of at least two regions. That is, one region composed of silicide of the first metal in contact with the silicon carbide layer, and the other region composed of carbide of the second metal on it. With a heat treatment described later, a region composed of the second metal may sometimes be formed on the region composed of the carbide of the second metal. The region composed of the silicide of the first metal (silicide region) means a region containing a larger amount of the silicide of the first metal than the carbide of the second metal. The region composed of the carbide of the second metal (carbide region) means a region containing a larger amount of the carbide of the second metal than the silicide of the first metal. The region composed of the second metal that is sometimes formed depending on the heating condition, is a region mainly composed of the second metal in which an atomic concentration of carbon in the carbide region is low. For example, it is the region mainly composed of titanium, tantalum or niobium.

Several technical methods can be offered for forming the laminated body of stacked layer structure where the region contacting the surface of the silicon carbide is the silicide region of the first metal and on which is provided the carbide region of the second metal. One method is depositing a metal film composed of the first metal on the surface of the silicon carbide followed by depositing on it a metal film composed of the second metal. That is, it is a method in which the film of the first metal for forming the silicide region in contact with the surface of the silicon carbide is formed beforehand followed by forming the film of the second metal that can easily form a carbide away from the surface of the silicon carbide. According to this method, since the silicide that offers low electrical resistance is provided in contact with the surface of the silicon carbide from the beginning, an ohmic electrode can be advantageously provided. However, on the other hand, as the film of the second metal that can easily form carbide by capturing carbon is provided away from the surface of the silicon carbide, the carbon that is released from the silicon carbide cannot be adequately captured. Therefore, formation of carbon clusters or voids in the region near the surface of the silicon carbide cannot be adequately controlled, and it will not be possible to provide a superior and stable electrode for silicon carbide having satisfactory adhesion to the silicon carbide.

On the other hand, the electrode for silicon carbide of the present invention can also be formed by using a laminated body in which the order of the above-mentioned layers is reversed, namely, the laminated body configured by providing a film of the second metal on the surface of the silicon carbide, followed by providing a film of the first metal. When employing the configuration provided with the layers in this order, since the film of the first metal that is to form the silicide that can constitute an ohmic contact with the silicon carbide is not provided in contact with the surface of the silicon carbide, a heat treatment becomes necessary to transfer the first metal to the surface of the silicon carbide and form a silicide region composed of a silicide of the first metal. Simultaneously, due to this heat treatment, the second metal initially provided on the surface of the silicon carbide, while forming carbide by capturing the carbon liberated from the silicon carbide, moves toward an upper direction away from the surface of the silicon carbide, which is the opposite movement to that of the first metal. Consequently, it becomes possible to form a structure, in which a silicide region of the first metal is provided on the surface of the silicon carbide, and a carbide region of the second metal is provide on it, where the initial order of the layers is reversed.

For example, the laminated body is constituted by first depositing a film of niobium (Nb) as the second metal on the surface of the silicon carbide of 4H type, followed by depositing a film of cobalt (Co) as the first metal. To just invert the order of the layers of this laminated body, heating in vacuum at a temperature of 800° C. to 1200° C. for a period of 1 to 30 minutes will be appropriate. For example, if heated in vacuum at 1100° C. for 30 minutes, a structure is created in which a cobalt silicide region is formed on the silicon carbide side, and a niobium carbide region is disposed on the cobalt silicide region. The thicker the first or second metal is, the more effective it is for inverting the order of the layers if the heating temperature is increased or the heating duration is prolonged.

The layer order can be inverted also by heating under the above conditions in an inert gas. The inert gas is a gas comprised of only argon (element symbol: Ar), helium (element symbol: He) or neon (element symbol: Ne) etc., for example. Or, it is a gas obtained by mixing inert gases such argon and helium. A gas containing nitrogen or oxygen (element symbol: O) is not suitable as a gas atmosphere for heating to invert the order of layers because it promotes the formation of nitride or oxide of the first or the second metal, which has a high electrical resistance.

Adding further restriction to the heating conditions can maintain a low atomic concentration of nitrogen in the region comprised of the carbide of the second metal. Specifically, the atomic concentration of nitrogen in a region where the carbide of the second metal is formed can be made not more than the atomic concentration of nitrogen within the silicon carbide. This region is a section where the atomic concentration of carbon is maximum, which indicates that the carbide of the second metal is maximum, in other words, the second metal that constitutes the carbide is maximum. With this, a formation of a high electrical resistance nitride of the second metal in the carbide region of the second metal by capturing the nitrogen present inside the silicon carbide can be suppressed.

The atomic concentration of nitrogen can be suppressed to a lower level as described above by applying heat to the laminated body, which is obtained by first depositing a film of the second metal on the silicon carbide followed by depositing a film of the first metal on it, to invert the order of layers by heating at 800° C. to 1200° C. for 1 to 30 minutes in an inert gas or under vacuum.

At temperatures more than 1200° C., since diffusion of nitrogen present in the silicon carbide into the film of the second metal becomes sharply significant, and the formation of nitride of the second metal in the region composed of carbide of the second metal becomes easy, it is not desirable. At a heating duration exceeding 30 minutes, here too, since diffusion of nitrogen into the film of the second metal becomes sharply significant, and the formation of nitride of the second metal in the region composed of carbide of the second metal becomes easy, it is not desirable. To suppress the diffusion of nitrogen from the inside of the silicon carbide, heating at lower temperatures is beneficial. However, heating at a temperature below 800° C. or heating for a period less than 1 minute will not make it possible to capture the carbon liberated from the silicon carbide to convert to carbide of the second metal with certainty in the first place.

Further, depending on the heating conditions, the atomic concentration of nitrogen in the entire region where the carbide of the second metal has been formed can be made not more than the atomic concentration of nitrogen within the silicon carbide. To suppress the atomic concentration of nitrogen to low levels thus, in particular, heating at a temperature not less than 850° C. and not more than 1150° C., for not less than 1 minute and not more than 30 minutes is optimal. Since the formation of nitride or carbon nitride of the second metal, which has high electrical resistance, in the carbide region of the second metal can be suppressed, it becomes possible to provide an electrode for silicon carbide with low current flow resistance.

The atomic concentrations or atomic concentration distribution of the second metal, carbon or nitrogen in the carbide region of the second metal can be measured, for example, by secondary ion mass spectrometry (SIMS). The atomic concentrations or atomic concentration distribution of the first metal, carbon or nitrogen in the silicide region of the first metal can also be measured by elemental analysis methods such as SIMS.

The electrical resistance of the carbide of the second metal is high compared to the silicide of the first metal. Due to this, if the thickness of the carbide region of the second metal is made not more than the thickness of the silicide region, it becomes possible to provide an electrode for silicon carbide having lower current flow resistance. The thickness of the silicide region of the first metal or the carbide region of the second metal depends on the thickness of the films of the first metal or the second metal provided initially on the silicon carbide. Accordingly, when providing a laminated body with initial order of layers, the film comprised of the second metal initially provided on the silicon carbide is provided at a film thickness that is not more than the thickness of the film comprised of the first metal.

It is necessary that the film comprised of the second metal shall have such a thickness so as to capture the carbon liberated from the silicon carbide and adequately form the carbide of the second metal. Under the heating condition in an inert gas or vacuum (temperature=800° C.-1200° C., time=1-30 minutes), the thickness necessary for adequately forming the carbide of the second metal is not less than 10 nanometers (unit of length: nm). Further, to suppress an unwanted increase in the electrical resistance, it is optimal to make the thickness to be not more than ½ of the thickness of the silicide region of the first metal. For example, the thickness of the initially deposited film of the first metal is made to be a nickel film of 100 nm thickness, and the thickness of the film of the second metal is made to be a niobium film of 15 nm thickness.

If the second metal element constituting the carbide region is comprised of a metal element with a free energy of nitride formation more than that of silicon (Si), then the formation of nitride or carbon nitride in the carbide region of the second metal can be further suppressed. Therefore, a metal having higher free energy of nitride formation than that of silicon is chosen as the second metal. In this manner, if a metal having a higher free energy of nitride formation is chosen as the second metal, it becomes advantageous in forming a carbide region in which the atomic concentration of nitrogen in the section where the atomic concentration of carbon is maximum is not more than the atomic concentration of nitrogen inside the silicon carbide. As examples of metal elements having a higher free energy of nitride formation than silicon (Si) can be offered, tantalum (element symbol: Ta), niobium (element symbol: Nb), aluminum (element symbol: Al), lanthanum (element symbol: La), scandium (element symbol: Sc) and magnesium (element symbol: Mg).

In addition, if a metal having a higher free energy of nitride formation than a free energy of carbide formation is chosen as the second metal, it becomes advantageous in forming a carbide region in which the atomic concentration of nitrogen in the entire carbide region is not more than the atomic concentration of nitrogen inside the silicon carbide. Niobium can be preferably used as the metal element whose free energy of nitride formation is more than that of silicon, and whose free energy of nitride formation is more than the free energy of carbide formation.

The carbide of niobium is for example NbC. The carbide region of niobium is a region composed by an aggregation of, for example, crystal grains of NbC. On the other hand, as silicides produced for the case where nickel is the first metal layer laminating with a film of niobium can be offered Ni₂Si, NiSi, NiSi₂ and Ni₃Si₂. As silicides produced for the case where cobalt is the first metal layer laminating with a film of niobium can be offered Co₂Si, CoSi and CoSi₂.

A film of niobium can be formed for example by high frequency sputtering method. A film of nickel or cobalt can also be formed by high frequency sputtering method. A Nickel or cobalt film may also be provided by chemical vapor deposition (CVD) method. In providing a film of nickel by Organometallic Chemical Vapor Deposition method, which is a type of CVD, for example, nickel carbonyl (molecular formula: Ni(CO)₄) or bis(1,5-cyclooctadiene)nickel (molecular formula: (1,5-C₈H₁₂)₂Ni) etc., can be used. As raw materials which can be employed for forming a film of cobalt, for example can be offered cobalt octacarbonyl (molecular formula: Co₂(CO)₈) or cyclopentadienyl cobalt dicarbonyl (molecular formula: C₅H₅Co(CO)₂).

Since the electrode for silicon carbide provided in the present invention, with its method of formation being special, has been configured so as to have a low contact resistance with the silicon carbide, and low overall current flow resistance, it becomes possible to provide a silicon carbide element of for example MOS (metal-oxide-semiconductor) devices, etc., whose ON resistance is also small and heat loss is also small. In addition, the electrode for silicon carbide provided in the present invention, since it is configured so as to prevent the formation of carbon clusters and voids in the surface of the silicon carbide, has no peeling off and has superior adhesion with silicon carbide. Therefore, it becomes possible to provide a silicon carbide diode, etc. having long-term operation reliability.

### EXAMPLE

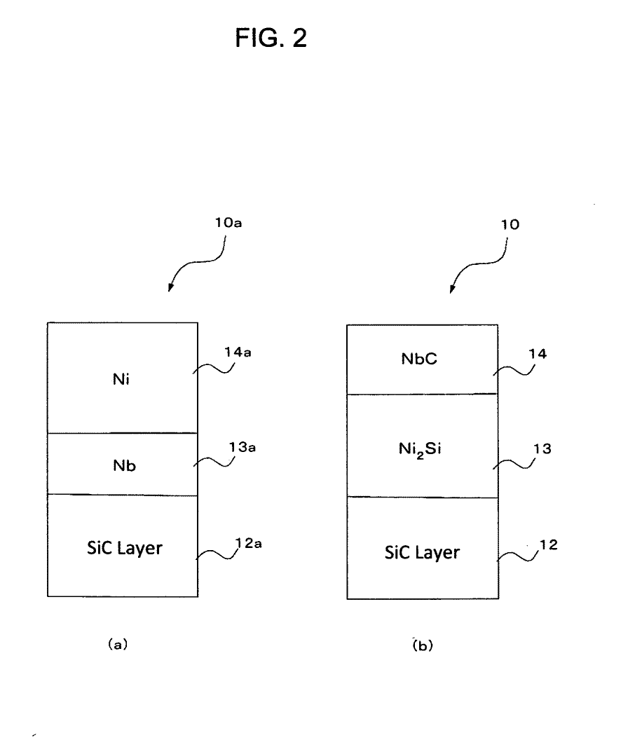

FIG. 2 is a figure depicting the steps of forming the electrode for silicon carbide in the example. (a) shows the first half, and (b) shows the second half. First, as shown in FIG. 2(a), on a silicon carbide layer 12a containing nitrogen, a niobium film 13a of thickness 20 nm was deposited as a second metal film, followed by depositing on it a nickel film 14a of 80 nm thickness as a first metal film to provide a laminated body 10a of above layer order. Next, an ohmic electrode for silicon carbide was provided by subjecting to a heat treatment to invert this layer order. That is, the laminated body 10a was subjected to a heat treatment in vacuum at 1000° C. for 5 minutes. With this, an electrode for silicon carbide 10 including a nickel carbide region 13 formed on a silicon carbide layer 12 and a niobium carbide region 14 formed on the nickel carbide region 13 was formed.

### COMPARATIVE EXAMPLE

By using a vanadium film and a titanium film in place of the niobium film in the above example, electrodes for silicon carbide were prepared by the same procedure and conditions as in the example.

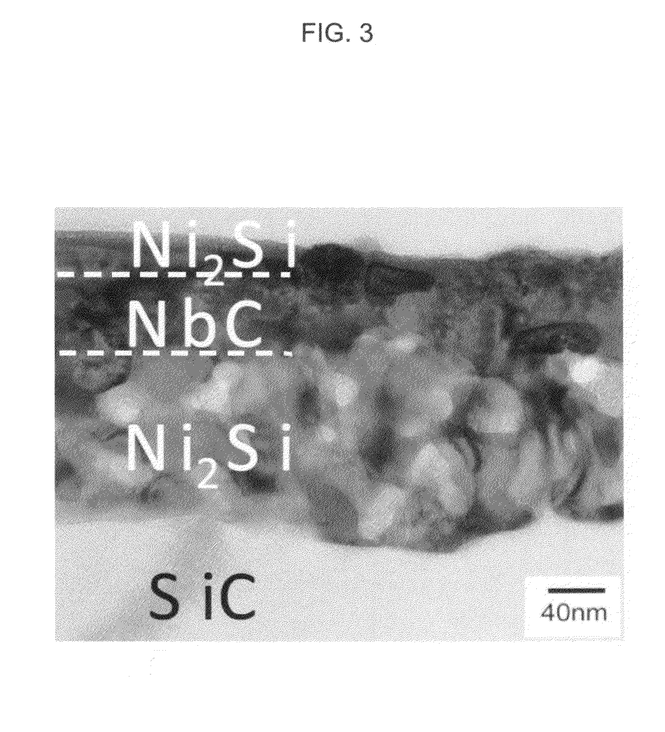

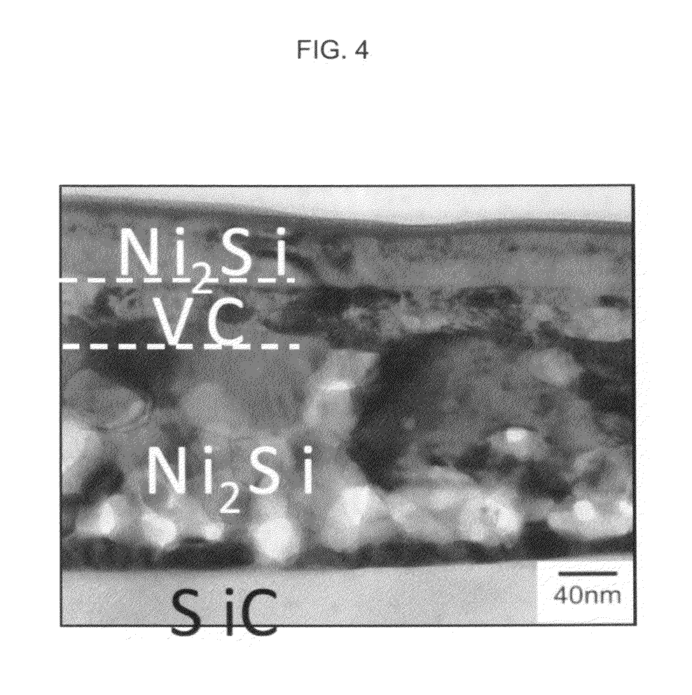

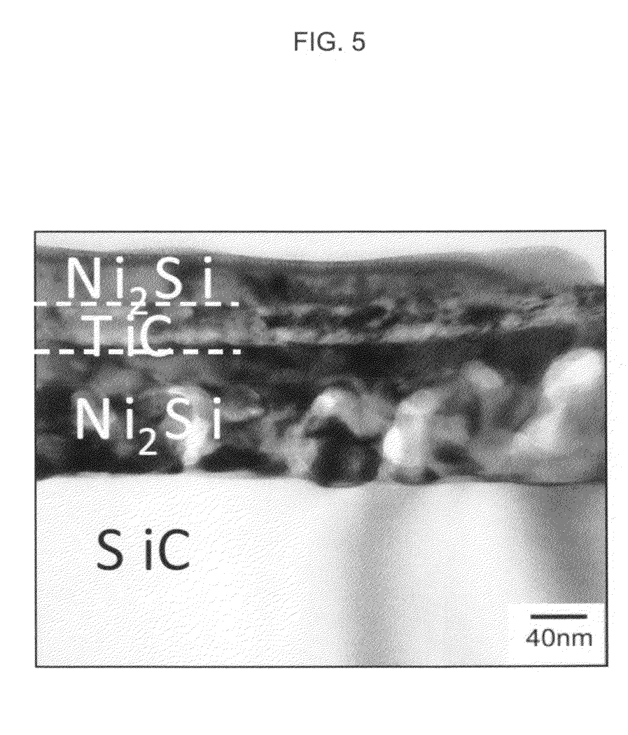

The surface structures of the obtained 3 types of electrodes for silicon carbide 10 were observed with transmission electron microscopy, and the results are shown in FIG. 3, FIG. 4 and FIG. 5.

FIG. 3 is for the case where the second metal film is the niobium film, FIG. 4 is for the case where the second metal film is the vanadium film, and FIG. 5 is for the case where the second metal film is the titanium film. After the heat treatment, each second metal film, while forming a carbide of the second metal by capturing the carbon liberated from the silicon carbide during the reaction of nickel with the silicon carbide to form the nickel silicide, reverses its position with respect to the first metal (Ni) and moves to the top away from the surface of the silicon carbide layer. As a result, it became possible to provide a structure where, with a reversed initial order of layers, a silicide region of the first metal (Ni) is formed on the surface of the silicon carbide, and a carbide region of the second metal is formed on the silicide region.

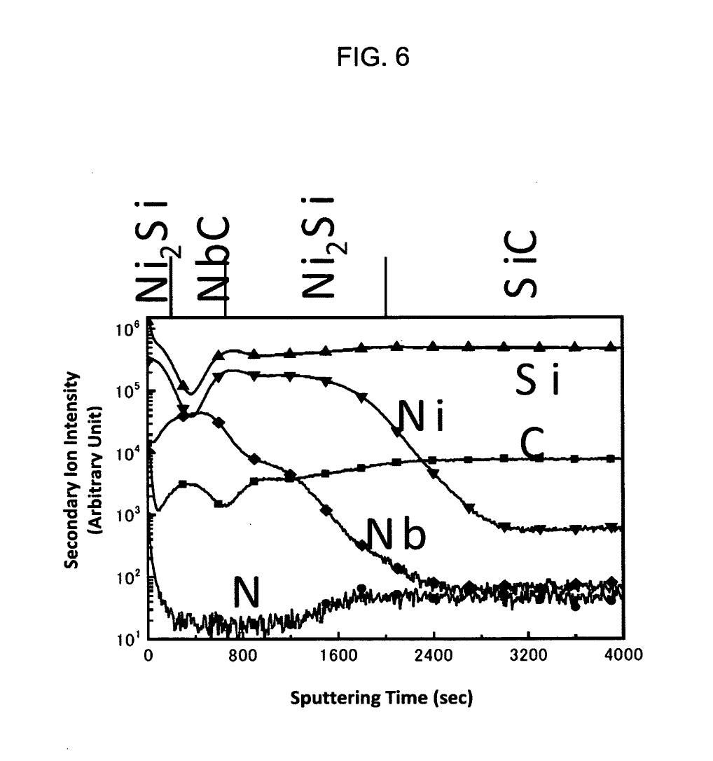

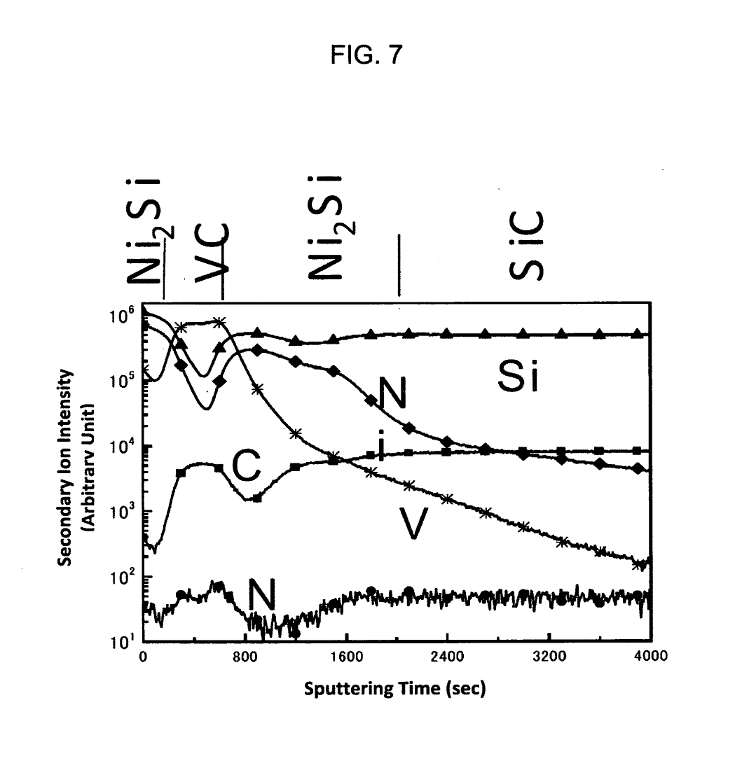

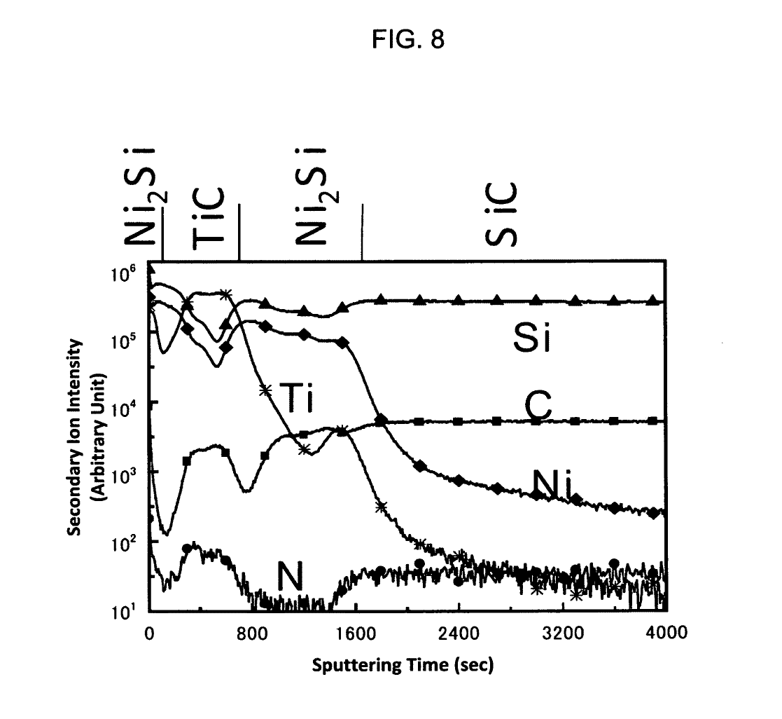

The composition distribution from the surface of the laminated body of the obtained electrode for silicon carbide towards the inside of the sample was determined with a Secondary Ion Mass Spectrometer. The results are shown in FIG. 6, FIG. 7 and FIG. 8. The vertical axis shows the measured current of the secondary ions that come out of the sample due to sputtering. The horizontal axis shows the sputtering time, and an increase of sputtering time corresponds to an increase of depth from the surface of the laminated body towards the inside of the sample. FIG. 6 is for the case wherein the second metal film is the niobium film, FIG. 7 is for the case wherein the second metal film is the vanadium film, and FIG. 8 is for the case wherein the second metal film is the titanium film. In all cases, high intensities of nickel and silicon are found at the surface of the laminated body, and nickel silicide (Ni₂Si) is found to be formed. In a region underneath the surface, high intensities of the second metal and carbon are found, and on the contrary, the intensities of nickel and silicon have decreased. This fact indicates the formation of a carbide of the second metal (NbC, VC, TiC) in this region. In a region underneath the second metal carbide region, high intensities of nickel and silicon are found, and nickel silicide (Ni₂Si) has been formed. Presence of nitrogen was confirmed inside the silicon carbide (SiC), and found to have become a nitrogen-doped n-type semiconductor.

Focusing attention on the distribution of nitrogen intensity in FIG. 6, FIG. 7 and FIG. 8, significant variations were observed based on the type of the second metal. In FIG. 6, in the region where niobium carbide (NbC) has been formed, the intensity of nitrogen is less than the intensity of nitrogen in the silicon carbide (SiC).

In FIG. 7, in the region where vanadium carbide (VbC) has been formed, the intensity of nitrogen is the same as or more than the intensity of nitrogen in the silicon carbide (SiC). This fact indicates that since vanadium has a strong tendency to form the nitride, it has removed the nitrogen contained in the silicon carbide, and formed a vanadium carbide containing nitrogen.

In FIG. 8, in the region where titanium carbide (TiC) has been formed, the intensity of nitrogen is the same as or more than the intensity of nitrogen in the silicon carbide (SiC). This fact indicates that, similar to the case of vanadium, titanium has removed the nitrogen contained in the silicon carbide, and formed a titanium carbide containing nitrogen. Incidentally, in any of FIG. 6, FIG. 7 and FIG. 8, in the carbide region where the carbide of the second metal has been formed, the atomic concentration of nitrogen is less than the atomic concentration of carbon. In addition, in FIG. 7 and FIG. 8, although the atomic concentration of nitrogen in the carbide region (VC, TiC) where the carbide of the second metal has been formed is high, it is not more than 3 times of nitrogen inside the silicon carbide layer.

Next, electrode patterns were provided on the silicon carbide surface by liftoff technique. Specifically, after providing electrode shape grooves in a resist film, a film of second metal (Nb, V, Ti) was formed inside the grooves by sputtering method, and then a film of the first metal (Ni) was formed. Then, by removing the resist film, the metal films remained only inside the groove, and an array of 120 μm×60 μm rectangular metal electrodes was obtained on the silicon carbide surface. These samples were subjected to a heat treatment in vacuum at 1000° C. for 5 minutes. When the current-voltage relationship between the electrodes was measured, a linear relation was obtained demonstrating ohmic features. However, when the heat treatment temperature was less than 800° C., the current-voltage relation was not linear, and displayed a non-linear relationship like Schottky. Even at the heat treatment temperature exceeding 1200° C., a non-linear relationship was found. Due to this, the experiments for measuring the contact resistivity were done at a temperature of not less than 800° C. and not more than 1200° C. The contact resistivity of the interface between the electrode and the silicon carbide was determined by TLM method (Transmission Line Method). The heat treatment of the samples was done in vacuum at 1000° C. for 5 minutes. The measurement temperatures were room temperature, 100° C. (373K), 200° C. (473K) and 300° C. (573 K).

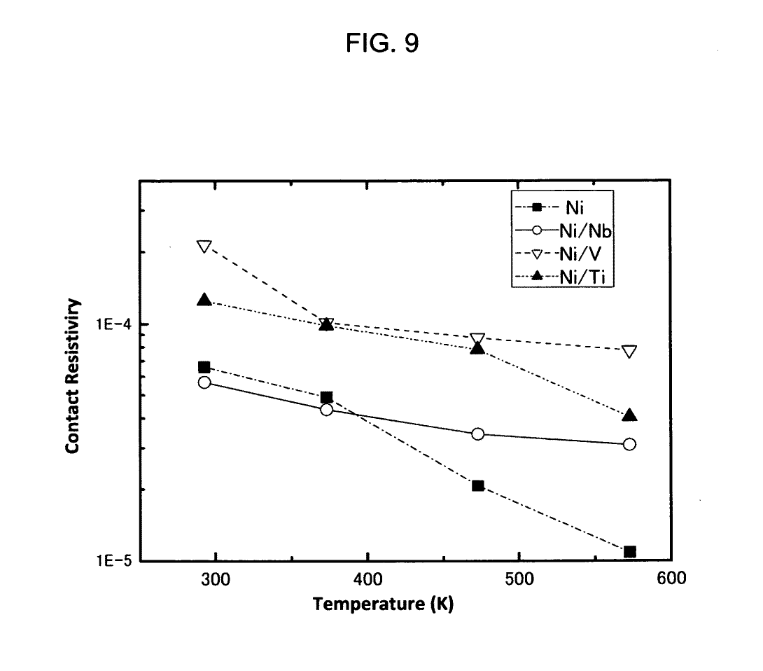

The results are shown in FIG. 9. For comparison, results of a conventionally most reported electrode of only Ni are also shown. In the case of the Ni electrode, the contact resistivity at room temperature was 7×10⁻⁵ Ωcm², and in the case of the Ni/Nb electrode with Nb as the second metal film, the contact resistivity was 6×10⁻⁵ Ωcm². In contrast to this, in the case of the Ni/Ti electrode or the Ni/V electrode having Ti or V as the second metal film, it is not less than 1×10⁻⁴ Ωcm², and displayed a higher contact resistivity compared to the Ni electrode and Ni/Nb electrode.

Regarding the reason for the Ni/Nb electrode showing a low contact resistivity similar to that of Ni as shown above, it is thought that since Nb does not pull out the nitrogen present in the SiC, there will be no change in the concentration of nitrogen which is a donor impurity of the SiC, and the electronic energy level in the SiC near the interface did not change. In contrast to this, regarding the reason for high contact resistivity shown by the Ni/V and the Ni/Ti electrodes, it is thought that since V and Ti pull out the nitrogen present in the SiC and form VC and TiC containing nitrogen, the concentration of nitrogen which is a donor impurity of the SiC decreases, and as a consequence of a fall in the Fermi energy of the SiC near the interface, the energy barrier for electron flow increases.

Since the electrode for silicon carbide provided in the present invention has low contact resistance and superior adhesion to the silicon carbide, it can be employed as an ohmic electrode for a pn junction type or Schottky junction type silicon carbide diode in large current handling applications for rectifying large element operating current. Moreover, these diodes can be optimally used for configuring silicon carbide semiconductor devices such as inverters, etc. Moreover, the electrode for silicon carbide provided in the present invention can also be employed as an ohmic electrode for a pn junction type transistor or a MOS field-effect transistor.

What is claimed is:

1. An electrode for silicon carbide comprising:
a silicide region which is provided in contact with a surface of a silicon carbide (SiC) layer, the silicide region containing a silicide of a first metal in more amount than a carbide of a second metal whose free energy of carbide formation is less than that of silicon (Si); and
a carbide region which is provided on the silicide region, the carbide region containing the carbide of the second metal in more amount than the silicide of the first metal.

2. The electrode for silicon carbide according to claim 1, wherein
the silicon carbide layer contains nitrogen, and
an atomic concentration of nitrogen in the carbide region is not more than an atomic concentration of nitrogen in the silicon carbide layer in a section where an atomic concentration of carbon (C) in the carbide region is maximum.

3. The electrode for silicon carbide according to claim 1, wherein
the silicon carbide layer contains nitrogen, and
an atomic concentration of nitrogen in the carbide region is not more than an atomic concentration of nitrogen in the silicon carbide layer.

4. The electrode for silicon carbide according to claim 1, wherein a thickness of the carbide region is not more than a thickness of the silicide region.

5. The electrode for silicon carbide according to claim 4, wherein a thickness of the carbide region is not less than 10 nanometer (nm), and is not more than one-half of the thickness of the silicide region.

6. The electrode for silicon carbide according to claim 1, wherein the second metal element is a metal element having a free energy of nitride formation higher than that of silicon.

7. The electrode for silicon carbide according to claim 6, wherein the second metal element is a metal element having a free energy of nitride formation higher than a free energy of carbide formation.

8. The electrode for silicon carbide according to claim 7, wherein the second metal element is niobium (Nb).

9. A silicon carbide semiconductor element comprising the electrode for silicon carbide according to claim 1 as an ohmic electrode.

10. A silicon carbide semiconductor device comprising the silicon carbide semiconductor element according to claim 9.

11. A method for forming an electrode for silicon carbide comprising:
depositing a second metal film on a surface of a silicon carbide layer, the second metal film including a second metal which has a free energy of carbide formation smaller than that of silicon;
depositing a first metal film on the second metal film, the first metal film including a first metal that can easily bond with silicon to form a silicide; and
heating a laminated body of the second metal film and the first metal film provided on the silicon carbide layer, thereby bonding the first metal with the silicon in the silicon carbide layer, bonding the second metal with the carbon of the silicon carbide layer, forming a silicide region containing larger amount of the silicide of the first metal than the carbide of the second metal on the silicon carbide layer, and forming a carbide region containing larger amount of the carbide of the second metal than the silicide of the first metal on the silicide region.

12. The method for forming the electrode for silicon carbide according to claim 11, wherein the silicon carbide layer contains nitrogen, and the laminated body of the second metal film and the first metal film is heated in an inert gas or in vacuum at a temperature of not less than 800° C. and not more than 1200° C. for a period of not less than 1 minute and not more than 30 minutes.

13. The method for forming the electrode for silicon carbide according to claim 11, wherein the silicon carbide layer contains nitrogen, and the laminated body of the second metal film and the first metal film is heated in an inert gas or in vacuum at a temperature of not less than 850° C. and not more than 1150° C. for a period of not less than 1 minute and not more than 15 minutes.

14. The method for forming the electrode for silicon carbide according to claim 11, wherein a film thickness of the second metal film is not more than a film thickness of the first metal film.

15. The method for providing the electrode for silicon carbide according to claim 14, wherein the film thickness of the second metal film is not less than 10 nm and not more than 150 nm, and the film thickness of the first metal film is not less than double of the film thickness of the second metal film and is not less than 20 nm and not more than 300 nm.

16. A method for forming an electrode for silicon carbide comprising:
depositing a second metal film on a surface of a silicon carbide layer, the second metal film including a second metal which has a free energy of carbide formation smaller than that of silicon;
depositing a first metal film on the second metal film, the first metal film including a first metal that can easily bond with silicon to form a silicide; and
heating a laminated body of the second metal film and the first metal film provided on the silicon carbide layer in an inert gas or in vacuum at a temperature of not less than 800° C. and not more than 1200° C. for a period of not less than 1 minute and not more than 30 minutes.
